(19) United States
(12) Patent Application Publication
(10) Pub. No.: US 2024/0315151 A1
(43) Pub. Date: Sep. 19, 2024

(54) SEMICONDUCTOR DEVICE AND METHOD FOR FABRICATING THE SAME

(71) Applicant: SK hynix Inc., Icheon (KR)

(72) Inventor: Yong Hun SUNG, Icheon (KR)

(21) Appl. No.: 18/448,486

(22) Filed: Aug. 11, 2023

(30) Foreign Application Priority Data
Mar. 15, 2023 (KR) 10-2023-0033972

(51) Int. Cl. H10N 70/00; H10B 63/00

(52) U.S. Cl. CPC H10N 70/841; H10B 63/80; H10N 70/021; H10N 70/8845

(57) ABSTRACT

A method for fabricating a semiconductor device includes forming a lower electrode layer containing carbon by applying AC power; forming a memory layer over the lower electrode layer; and forming an upper electrode layer containing carbon over the memory layer without applying AC power.

### CROSS-REFERENCE TO RELATED APPLICATIONS

The present application claims priority of Korean Patent Application No. 10-2023-0033972, filed on Mar. 15, 2023, which is incorporated herein by reference in its entirety.

### BACKGROUND

### 1. Field

Exemplary embodiments of the present disclosure relate to a semiconductor technology, and more particularly, to a semiconductor device including a memory cell, and a method for fabricating the same.

### 2. Description of the Related Art

Recent trend for miniaturization, low power consumption, high performance, and diversification of electronic devices requires semiconductor devices capable of storing information in diverse electronic devices, such as computers and portable communication devices, and researchers are studying to achieve these purposes. Among the semiconductor devices are those capable of storing data using the characteristic of switching between different resistance states according to the applied voltage or current, such as a resistive random access memory (RRAM), a phase-change random access memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device capable of improving operation characteristics of a memory cell and preventing process defects, and a method for fabricating the semiconductor device.

In accordance with an embodiment of the present disclosure, a method for fabricating a semiconductor device includes forming a lower electrode layer containing carbon by applying AC power; forming a memory layer over the lower electrode layer; and forming an upper electrode layer containing carbon over the memory layer without applying AC power.

In accordance with another embodiment of the present disclosure, a method for fabricating a semiconductor device, includes: forming a lower electrode layer; forming a memory layer over the lower electrode layer; forming a first upper electrode layer containing carbon over the memory layer; and forming a second upper electrode layer containing carbon over the first upper electrode layer, wherein DC power applied when forming the first upper electrode layer is smaller than DC power applied when forming the second upper electrode layer.

In accordance with another embodiment of the present disclosure, a semiconductor device, includes: a lower electrode containing carbon; a memory pattern positioned over the lower electrode; and an upper electrode including a first upper electrode and a second upper electrode, the first upper electrode positioned over the memory pattern and containing carbon, the second upper electrode positioned over the first upper electrode and containing carbon, wherein a density of the first upper electrode is greater than a density of the second upper electrode.

### BRIEF DESCRIPTION OF THE DRAWINGS

FIGS. 1 and 2 illustrate a semiconductor device in accordance with an embodiment of the present disclosure.

FIG. 3 is a flowchart describing a method for forming a memory cell in accordance with an embodiment of the present disclosure.

FIG. 4 is a graph showing an experimental result of the surface roughness of a carbon-containing layer according to process conditions.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale, and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

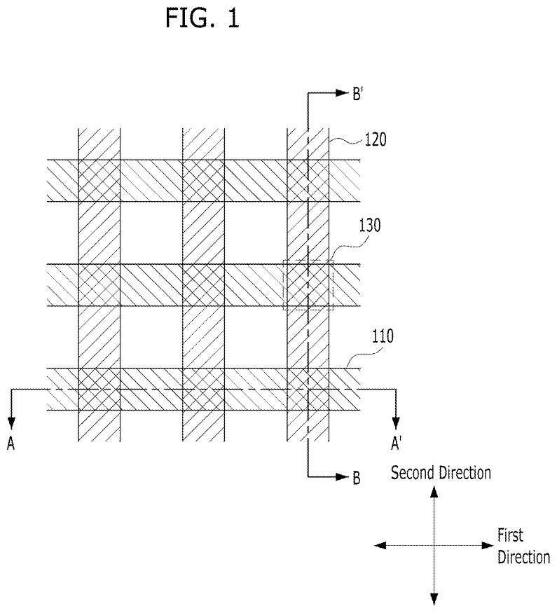

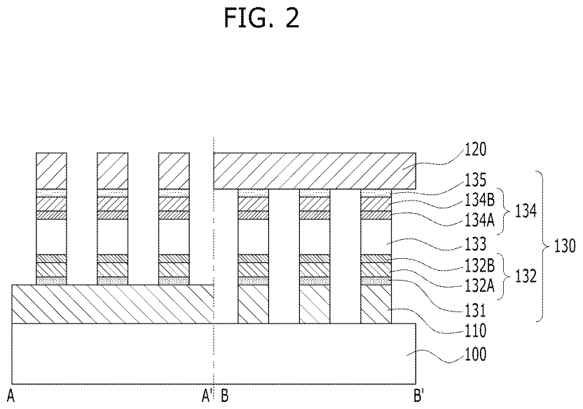

FIGS. 1 and 2 illustrate a semiconductor device in accordance with an embodiment of the present disclosure. FIG. 1 shows a plan view, and FIG. 2 shows cross-sectional views taken along a line A-A′ and a line B-B′ of FIG. 1.

Referring to FIGS. 1 and 2, the semiconductor device may include a substrate 100, a lower conductive line 110 formed over the substrate 100 and extending in a first direction, an upper conductive line 120 formed to be spaced apart from the lower conductive line 110 over the lower conductive line 110 and extending in a second direction crossing the first direction, and a memory cell 130 positioned at the intersection of the lower conductive line 110 and the upper conductive line 120 between the lower conductive line 110 and the upper conductive line 120.

The substrate 100 may include a semiconductor material, such as silicon. A predetermined lower structure (not shown) may be formed in the substrate 100. For example, the substrate 100 may include a driving circuit (not shown) electrically connected to the lower conductive line 110 and/or the upper conductive line 120 to control an operation of the memory cell 130.

Each of the lower conductive line 110 and the upper conductive line 120 may include one of various conductive materials, for example, a metal, such as platinum (Pt), tungsten (W), aluminum (Al), copper (Cu), tantalum (Ta), or the like, a metal nitride, such as titanium nitride (TiN), tantalum nitride (TaN), or the like, or a combination thereof. Each of the lower conductive line 110 and the upper conductive line 120 may have a single-layer structure or a multi-layer structure. The lower conductive line 110 and the upper conductive line 120 may be coupled to lower and upper ends of the memory cell 130, respectively, to transfer a voltage or current to the memory cell 130 so as to drive the memory cell 130. When the lower conductive line 110 functions as a word line, the upper conductive line 120 may function as a bit line. Conversely, when the lower conductive line 110 functions as a bit line, the upper conductive line 120 may function as a word line.

The memory cell 130 may be a device that stores different data according to a level of the voltage or current applied to the lower conductive line 110 and the upper conductive line 120. For example, the memory cell 130 may have a quadrangular shape in which both sidewalls in the first direction are aligned with the upper conductive line 120 and both sidewalls in the second direction are aligned with the lower conductive line 110. However, the concept and spirit of the present disclosure are not limited thereto, and as long as the memory cell 130 overlaps with the intersection of the lower conductive line 110 and the upper conductive line 120, a planar shape of the memory cell 130 may be modified diversely.

According to this embodiment of the present disclosure, the memory cell 130 may include a memory pattern 133 for storing data, a lower electrode 132 interposed between the memory pattern 133 and the lower conductive line 110, a lower resistance pattern 131 interposed between the lower electrode 132 and the lower conductive line 110, an upper electrode 134 interposed between the memory pattern 133 and the upper conductive line 120, and an upper resistance pattern 135 interposed between the upper electrode 134 and the upper conductive line 120.

The memory pattern 133 may store different data by switching between different resistance states according to the applied voltage or current. That is, the memory pattern 133 has a variable resistance characteristic. The memory pattern 133 may include one of various materials used for memories including an RRAM, a PRAM, an FRAM, an MRAM, and the like. For example, the memory pattern 133 may include a metal oxide such as a transition metal oxide, a perovskite material, a phase-change material such as a chalcogenide-based material, a ferroelectric material, a ferromagnetic material, or the like. The memory pattern 133 may have a single-layer structure or a multi-layer structure.

The memory pattern 133 may have a variable resistance characteristic of switching between different resistance states according to the applied voltage or current, and may have a selector characteristic of being turned on or off based on a predetermined threshold voltage. Such a memory pattern 133 may be referred to as a self-selecting memory. Since the self-selecting memory has different threshold voltages in different resistance states, the self-selecting memory may function as a memory as well as a selector. The memory pattern 133 may include a chalcogenide alloy, and may switch between a high-resistance state and a low-resistance state according to the migration of elements in the chalcogenide alloy. Here, the threshold voltage in the high-resistance state and the threshold voltage in the low resistance state may be different from each other.

The lower electrode 132 may be interposed between the lower conductive line 110 and the memory pattern 133, and may electrically connect the lower conductive line 110 and the memory pattern 133 while physically separating them from each other. The lower electrode 132 may include carbon. Furthermore, the lower electrode 132 may include a stacked structure of a first lower electrode 132A and a second lower electrode 132B, both of which have different characteristics.

The lower electrode 132 may be required to be densified while having low surface roughness. If the surface roughness of the lower electrode 132 is large, since a lower surface of the memory pattern 133 contacts the rough surface of the lower electrode 132 and an upper surface of the memory pattern 133 contacts a lower surface of the upper electrode 134 having a low roughness, an asymmetry of roughness may occur between the lower surface and the upper surface of the memory pattern 133. The asymmetry of roughness may degrade operation characteristics of the memory cell 130. For example, an operation of the memory cell 130 may be non-uniform and a read window margin of the memory cell 130 may be reduced.

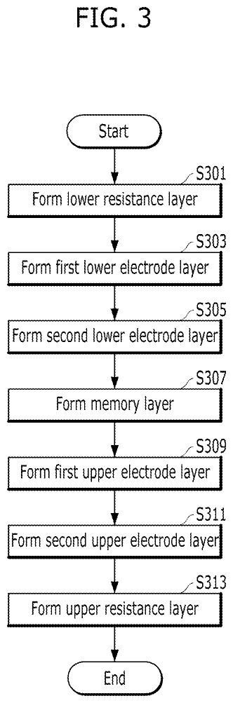

Therefore, it may be necessary to make the roughness of the lower and upper surfaces of the memory pattern 133 symmetrical by reducing the surface roughness of the lower electrode 132. Also, if the density of the lower electrode 132 is low, defects, such as intermixing and bursting resulting from the intermixing, may occur at an interface between the lower electrode 132 and a layer below the lower electrode 132, for example, the lower resistance pattern 131. This may adversely affect the operation characteristics of the memory cell 130. Therefore, it may be necessary to suppress or reduce the defects at the interface between the lower electrode 132 and the lower resistance pattern 131 by increasing the density of the lower electrode 132. A method for forming the lower electrode 132 for this purpose will be described in detail with reference to FIG. 3.

The upper electrode 134 may be interposed between the upper conductive line 120 and the memory pattern 133, and may electrically connect the upper conductive line 120 and the memory pattern 133 while physically separating them from each other. The upper electrode 134 may include carbon. Furthermore, the upper electrode 134 may include a stacked structure of a first upper electrode 134A and a second upper electrode 134B, both of which have different characteristics. Unlike the lower electrode 132, the upper electrode 134 is not required to have a low surface roughness. This is because the lower surface of the upper electrode 134 contacts the memory pattern 133 instead of an upper surface of the upper electrode 134 contacting the memory pattern 133. On the other hand, the upper electrode 134 may be required to be densified like the lower electrode 132. If the density of the upper electrode 134 is low, a material forming the upper resistance pattern 135 may pass through the upper electrode 134 to be mixed with a material forming the memory pattern 133, and thus it may cause defects such as bursting of the memory pattern 133. This may adversely affect the operation characteristics of the memory cell 130. Therefore, it may be necessary to suppress or reduce the occurrence of the defects by increasing the density of the upper electrode 134. A method for forming the upper electrode 134 that may suppress or reduce the defects by increasing the density of the upper electrode 134 will be described in detail with reference to FIG. 3.

The lower resistance pattern 131 may be positioned between the lower conductive line 110 and the lower electrode 132. When a large amount of current or voltage is supplied to drive the memory cell 130, the lower resistance pattern 131 may prevent or reduce the occurrence of an operation failure of the memory cell 130 that may occur as an overshooting current or a spike current flows through the memory cell 130. The lower resistance pattern 131 may include a material having higher resistance than the lower electrode 132 and the upper electrode 134. For example, the lower resistance pattern 131 may include tungsten silicon nitride (WSiN). Also, the lower resistance pattern 131 may have a thickness of scores of angstroms, for example, a thickness of approximately 10 to 200 angstroms, more preferably, a thickness of approximately 30 to 50 angstroms.

The upper resistance pattern 135 may be positioned between the upper conductive line 120 and the upper electrode 134. When a large amount of current or voltage is supplied to drive the memory cell 130, the upper resistance pattern 135 may prevent or reduce the occurrence of an operation failure of the memory cell 130 that may occur as an overshooting current or a spike current flows through the memory cell 130. The upper resistance pattern 135 may include a material having higher resistance than the lower electrode 132 and the upper electrode 134. For example, the upper resistance pattern 135 may include tungsten silicon nitride (WSiN). Also, the upper resistance pattern 135 may have a thickness of scores of angstroms, for example, a thickness of approximately 10 to 200 angstroms, more preferably, a thickness of approximately 30 to 50 angstroms.

The lower resistance pattern 131 and the upper resistance pattern 135 may be formed of the same material and of the same thickness. In other words, the lower resistance pattern 131 and the upper resistance pattern 135 may be formed to be symmetrical with respect to the memory pattern 133 interposed therebetween. However, the concept and spirit of the present disclosure are not limited thereto. In another embodiment, at least one of the materials and the thicknesses of the lower resistance pattern 131 and the upper resistance pattern 135 may be different. Also, at least one of the lower resistance pattern 131 and the upper resistance pattern 135 may be omitted.

A method for fabricating a semiconductor device according to the embodiment of the present disclosure is briefly described as follows.

First, a first conductive layer for forming the lower conductive line 110 and material layers for forming the memory cells 130 may be sequentially formed over the substrate 100. The material layers for forming the memory cells 130 may include a lower resistance layer, a lower electrode layer, a memory layer, an upper electrode layer, and an upper resistance layer.

Subsequently, the first conductive layer for forming the lower conductive line 110 and the material layers for forming the memory cells 130 may be etched using a line-shaped mask pattern that extends in the first direction. As a result, the lower conductive line 110 may be formed, and a stacked structure of material layer patterns having a line shape overlapping with the lower conductive line 110 may be formed over the lower conductive line 110. A space between two adjacent lower conductive lines 110 and a space between two adjacent stacked structures of the material layer patterns may be filled with a dielectric material.

Subsequently, a second conductive layer for forming the upper conductive line 120 may be formed over the stacked structures of the material layer patterns and the dielectric material.

Subsequently, the upper conductive line 120 and the memory cells 130 may be formed by etching the second conductive layer and the stacked structures of the material layer patterns using a line-shaped mask pattern extending in the second direction.

According to this embodiment of the present disclosure, the material layers for forming the memory cells 130 may be patterned together with the lower conductive line 110 and the upper conductive line 120. However, the concept and spirit of the present disclosure are not limited thereto. According to another embodiment of the present disclosure, the material layers for forming the memory cells 130 may be patterned separately from the lower conductive line 110 and the upper conductive line 120. In other words, after forming the lower conductive line 110 and filling the space between the two adjacent lower conductive lines 110 with the dielectric material, pillar-shaped memory cells 130 may be formed by depositing the material layers for forming the memory cells 130 over the lower conductive line 110 and the dielectric material and then patterning the material layers. Subsequently, after filling spaces between the pillar-shaped memory cells 130 with the dielectric material, the upper conductive line 120 may be formed thereon.

When the lower resistance layer, the lower electrode layer, the memory layer, the upper electrode layer, and the upper resistance layer are patterned as described above, the lower resistance pattern 131, the lower electrode 132, the memory pattern 133, the upper electrode 134, and the upper resistance pattern 135 may be formed.

In any case, it is required to form the material layers for forming the memory cells 130, which will be described in more detail with reference to FIG. 3.

FIG. 3 is a flowchart describing a method for forming memory cells in accordance with an embodiment of the present disclosure. The method will be described with reference to FIG. 2.

Referring to FIG. 3, a lower resistance layer may be formed over a lower structure, for example, a first conductive layer for forming the lower conductive line 110 in step S301.

Subsequently, a first lower electrode layer containing carbon may be formed over the lower resistance layer in step S303. The first lower electrode layer may be formed by one of various physical or chemical deposition methods. For example, the first lower electrode layer may be formed by a Physical Vapor Deposition (PVD) method.

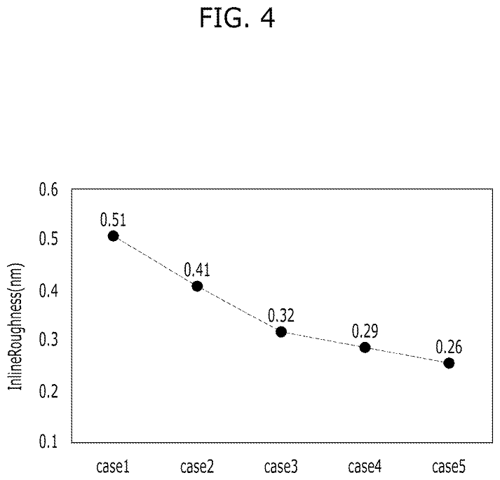

Here, during the process of depositing the first lower electrode layer, AC power may be applied. This is because, assuming that other process conditions are the same, a carbon-containing layer which is deposited while applying AC power has a lower surface roughness and higher density than a carbon-containing layer which is deposited without applying AC power, which was experimentally confirmed (refer to FIG. 4 below). Here, AC power of approximately 100 W to 500 W may be applied to achieve the low surface roughness and high density.

A carbon layer containing a relatively high concentration of nitrogen may be used as the first lower electrode layer. Here, the carbon layer containing nitrogen may refer to a layer including carbon and nitrogen, where a main element is carbon and nitrogen is an additive element. This is because the carbon layer doped with a high concentration of nitrogen has a lower surface roughness while having a resistivity similar to that of an undoped carbon layer, which was also experimentally confirmed (refer to FIG. 4 below). For example, the nitrogen content of the first lower electrode layer for reducing surface roughness may be approximately 1 at % or more and approximately 15 at % or less, more preferably approximately 3 at % or more and approximately 10 at % or less.

However, when the first lower electrode layer is a carbon layer containing a high concentration of nitrogen and when a memory layer is directly formed on the first lower electrode layer, the interface resistance between the first lower electrode layer and the memory layer may increase by nitrogen doping between the first lower electrode layer and the memory layer. The increase in the interface resistance may increase an operating voltage of the memory cells 130. This problem may be solved by interposing a second lower electrode layer between the first lower electrode layer and the memory layer. In other words, the following step S305 may be performed.

Subsequently, the second lower electrode layer containing carbon may be formed over the first lower electrode layer in step S305. The second lower electrode layer may be formed by one of various physical or chemical deposition methods. For example, the second lower electrode layer may be formed using the same deposition method as that of the first lower electrode layer, for example, using the Physical Vapor Deposition (PVD) method.

As the second lower electrode layer, a carbon layer containing no nitrogen or a relatively low concentration of nitrogen may be used. The nitrogen content of the second lower electrode layer may be lower than that of the first lower electrode layer. For example, the nitrogen content of the second lower electrode layer may be approximately 0 at % or more and approximately 3 at % or less. In this case, since the second lower electrode layer contacts a memory layer, which is to be described later, the problem of increasing the interface resistance between the first lower electrode layer and the memory layer may be improved.

Furthermore, even though the second lower electrode layer does not contain nitrogen or contains nitrogen at a relatively low concentration, the surface roughness thereof may be maintained low. The method for forming the second lower electrode layer is described as follows.

First of all, it is possible to densify the second lower electrode layer while reducing the surface roughness of the second lower electrode layer by applying AC power. For example, AC power of approximately 100 W to 500 W may be applied. Also, the AC power applied when the second lower electrode layer is formed may be substantially the same as the AC power applied when the first lower electrode layer is formed. Furthermore, for example, the process for forming the first lower electrode layer and the process for forming the second lower electrode layer may be performed in situ, and deposition thereof may be performed under the same process conditions, except for a flow rate of a nitrogen-containing gas (e.g., N₂ gas) that is used during the deposition. The flow rate of the nitrogen-containing gas that is used when the second lower electrode layer is deposited may be smaller than the flow rate of the nitrogen-containing gas that is used when the first lower electrode layer is deposited.

Also, since the second lower electrode layer having a relatively small thickness is formed over the first lower electrode layer having a low surface roughness, the surface roughness of the second lower electrode layer may also be reduced according to the low surface roughness of the first lower electrode layer. The thickness of the second lower electrode layer may be smaller than the thickness of the first lower electrode layer. For example, the second lower electrode layer may have a thickness of approximately 10 to 50 angstroms. Alternatively, for example, the second lower electrode layer may have a thickness of approximately 10 to 30% of the thickness of the first lower electrode layer.

Although this embodiment of the present disclosure describes the case of forming the second lower electrode layer over the first lower electrode layer, but the concept and spirit of the present disclosure are not limited thereto. If the first lower electrode layer has a sufficiently low surface roughness by adjusting the AC power, it may not be necessary to use a carbon layer containing a high concentration of nitrogen. In other words, the first lower electrode layer may be formed of a carbon layer containing a concentration of nitrogen that does not cause an increase in the interface resistance or causes insignificant increase in the interface resistance even though the first lower electrode layer directly contacts the memory layer. In this case, the second lower electrode layer may be omitted.

Subsequently, the memory layer may be formed over the second lower electrode layer (or on the first lower electrode layer when the second lower electrode layer is omitted) in step S307.

Subsequently, a first upper electrode layer containing carbon may be formed over the memory layer in step S309. The first upper electrode layer may be formed by one of various physical or chemical vapor deposition methods. For example, the first upper electrode layer may be formed by a Physical Vapor Deposition (PVD) method.

Since the first upper electrode layer contacts the memory layer, it may require a high density that is similar to the density of the first lower electrode layer and/or the density of the second lower electrode layer. However, when AC power is applied for high density, the memory layer may be attacked by the AC power, and defects, such as voids, may occur in the memory layer. Therefore, when the first upper electrode layer is deposited, it is possible to increase the density of the first upper electrode layer by applying relatively low DC power in a state that AC power is not applied, which has been experimentally confirmed (see Table 1 below). For example, DC power of approximately 100 W to 900 W may be applied to obtain the high density of the first upper electrode layer. Here, the AC power may be approximately OW. DC power may be applied even when the first and second lower electrode layers are deposited, and the DC power may have a range of approximately 1000 W to 5000 W. Therefore, the DC power applied when the first upper electrode layer is deposited is lower than the DC power applied when the first and second lower electrode layers are deposited.

Also, a carbon layer containing no nitrogen or a relatively low concentration of nitrogen may be used as the first upper electrode layer. This may be to prevent an increase in the interface resistance between the first upper electrode layer and the memory layer. For example, the nitrogen content of the first upper electrode layer may be approximately 0 at % or more and approximately 3 at % or less. For example, the first upper electrode layer may have a thickness of approximately 10 to 50 angstroms. Also, for example, the first upper electrode layer and the second lower electrode layer may be formed of substantially the same material and thickness. In other words, the first upper electrode layer and the second lower electrode layer may be formed to be symmetrical with respect to the memory layer interposed therebetween. However, the concept and spirit of the present disclosure are not limited thereto, and at least one of the materials and the thicknesses of the first upper electrode layer and the second lower electrode layer may be different from each other.

Meanwhile, when the first upper electrode layer is deposited by applying the low DC power as described above, the density thereof may be increased, while the compressive stress is increased. The compressive stress may cause voids to be created in the memory layer. Accordingly, a heat treatment process may be performed after the first upper electrode layer is formed in order to release the compressive stress so that the generation of voids is suppressed or reduced and the film quality of the memory layer is reinforced. The heat treatment process may be performed at a temperature of approximately 100° C. to 500° C. for several minutes.

Subsequently, a second upper electrode layer containing carbon may be formed over the first upper electrode layer in step S311. The second upper electrode layer may be formed by one of various physical or chemical deposition methods. For example, the second upper electrode layer may be formed by a Physical Vapor Deposition (PVD) method.

Deposition of the second upper electrode layer may be performed without applying AC power to prevent the memory layer from being attacked by the AC power. Also, the second upper electrode layer may be deposited in a state that a relatively high DC power is applied. This is because the second upper electrode layer does not contact the memory layer, and thus, unlike the first upper electrode layer, the second upper electrode layer does not require high density. In other words, the second upper electrode layer does not need to endure disadvantages that may be caused by the application of low DC power, such as generation of voids that may be caused by the application of compressive stress. For example, DC power of approximately 1000 W to 5000 W may be applied when the second upper electrode layer is deposited. The DC power applied when the second upper electrode layer is deposited may be greater than the DC power applied when the first upper electrode layer is deposited.

Also, a carbon layer containing a relatively high concentration of nitrogen may be used as the second upper electrode layer. In this case, the surface roughness of the second upper electrode layer may be reduced so that a layer formed over the second upper electrode layer, for example, an upper resistance layer, may be uniformly formed. For example, the nitrogen content of the second upper electrode layer may be greater than approximately 3 at % and equal to or less than approximately 10 at %.

The second upper electrode layer may be thicker than the first upper electrode layer. The second upper electrode layer may have substantially the same thickness as that of the first lower electrode layer or have a thickness greater than that of the first lower electrode layer, and may include substantially the same material as that of the first lower electrode layer. For example, the second upper electrode layer and the first lower electrode layer may be formed to be symmetrical with respect to the memory layer interposed therebetween. However, the concept and spirit of the present disclosure are not limited thereto, and at least one of the materials and the thicknesses of the second upper electrode layer and the first lower electrode layer may be different from each other.

For example, the process for forming the second upper electrode layer may be performed in situ along with the process for forming the first upper electrode layer, and the second upper electrode layer may be deposited under the same process conditions as those of the first upper electrode layer, for example, under the condition that the AC power of approximately OW is applied, except for a flow rate of a nitrogen-containing gas (e.g., N₂ gas) used during the deposition and DC power. The flow rate of the nitrogen-containing gas used when the second upper electrode layer is deposited may be greater than the flow rate of the nitrogen-containing gas used when the first upper electrode layer is deposited.

Subsequently, the upper resistance layer may be formed over the second upper electrode layer in step S313. As a result, the material layers for forming a memory cell may be formed, and then the material layers are patterned to form the memory cells 130 of FIGS. 1 and 2.

To sum up, the low surface roughness and the high density of the lower electrode layer may be satisfied by applying AC power when the lower electrode layer is formed. Accordingly, the operation characteristics of the memory cell may be improved, and the interface defects that may occur with the layer positioned below the lower electrode layer, for example, the lower resistance layer, may be prevented or reduced.

Since the lower electrode layer has a stacked structure in which the first lower electrode layer including a carbon layer having a relatively high nitrogen content and the second lower electrode layer including a carbon layer having a relatively low nitrogen content are stacked, the interfacial characteristics with the memory layer may be improved.

Since the first upper electrode layer may be formed with low DC power in a state that AC power is not applied, the first upper electrode layer may be highly densified. In this case, it is possible to prevent or reduce interface defects with the memory layer positioned below the first upper electrode layer. Furthermore, by forming the second upper electrode layer with high DC power in a state that AC power is not applied, attack on the memory layer may be prevented or reduced.

FIG. 4 is a graph showing an experimental result of the surface roughness of a carbon-containing layer according to process conditions.

Here, a first case case1 shows the surface roughness of a carbon-containing layer that is formed under predetermined process conditions as a comparative example. A second case case2 shows the surface roughness when changing the carbon-containing layer to a multi-layer under the same process conditions as those of the first case case1. A third case case3 shows the surface roughness when further lowering a temperature under the same process conditions as those of the first case case1. A fourth case case4 shows the surface roughness when further increasing a nitrogen flow rate under the same process conditions as those of the first case case1. A fifth case case5 shows the surface roughness when additionally applying AC power under the same process conditions as those of the first case case1.

Referring to FIG. 4, it may be seen that the carbon-containing layer has the lowest surface roughness in the fifth case case5. In other words, it may be seen that the application of AC power is the most effective factor in lowering the surface roughness of the carbon-containing layer.

Also, in the fourth case case4, it may be seen that the carbon-containing layer has the second lowest surface roughness. In other words, the nitrogen content may be another effective factor for lowering the surface roughness.

Table 1 below describes electrode characteristics of memory cells formed according to the method of the embodiment of the present disclosure.

TABLE 1

| | CASE 1 | CASE 2 | CASE 3 | CASE 4 |
|---|---|---|---|---|
| Density (g/cm3) | 1.92 | 2.41 | 2.40 (2.41) | 2.38 (2.10) |
| Roughness (nm) | 0.72 | 0.21 | 0.30 (0.27) | 0.30 (0.77) |

Here, case 1 shows the density and surface roughness of the carbon-containing layer of the comparative example. Case 2 to case 4 show the density and surface roughness of the carbon-containing layer used as an electrode according to this embodiment of the present disclosure. In particular, case 2 shows the density and surface roughness of a first lower electrode. Case 3 shows the density and surface roughness of a second lower electrode. Here, in case 3, values in parenthesis show the density and surface roughness of an entire lower electrode including the first and second lower electrodes. Case 4 shows the density and surface roughness of a first upper electrode. Here, in case 4, values in parenthesis show the density and surface roughness of an entire upper electrode including the first and second upper electrodes.

Referring to Table 1, it may be seen that, compared to the comparative example, the densities of the first and second lower electrodes are greatly increased while their surface roughnesses are greatly decreased. Also, it may be seen that the density of the entire lower electrode is increased and the surface roughness thereof is decreased. Also, it may be seen that the density of the first upper electrode is greatly increased compared to the comparative example. The entire upper electrode has larger density than the comparative example, but the density of the entire upper electrode is lower than the density of the first upper electrode. This is because the density of the second upper electrode is lower than that of the first upper electrode. Also, the density of the second upper electrode may be lower than the densities of the first and second lower electrodes. Also, the surface roughness of the entire upper electrode is greatly increased compared to that of the comparative example because the surface roughness of the second upper electrode is greatly increased compared to that of the first upper electrode. Also, the surface roughness of the second upper electrode may be greater than those of the first and second lower electrodes.

According to the embodiment of the present disclosure, a semiconductor device capable of improving operation characteristics of a memory cell and preventing process defects, and a method for fabricating the semiconductor device are provided.

While the present disclosure has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a lower electrode layer containing carbon by applying AC power;
forming a memory layer over the lower electrode layer; and
forming an upper electrode layer containing carbon over the memory layer without applying AC power.

2. The method of claim 1, wherein the AC power applied when forming the lower electrode layer has a range of 100 W to 500 W.

3. The method of claim 1, wherein the forming of the lower electrode layer includes:
forming a first lower electrode layer; and
forming a second lower electrode layer over the first lower electrode layer,
wherein a nitrogen content of the first lower electrode layer is greater than a nitrogen content of the second lower electrode layer.

4. The method of claim 3, wherein the second lower electrode layer contains no nitrogen.

5. The method of claim 3, wherein a thickness of the first lower electrode layer is greater than a thickness of the second lower electrode layer.

6. The method of claim 1, wherein the forming of the upper electrode layer includes:
forming a first upper electrode layer; and
forming a second upper electrode layer over the first upper electrode layer,
wherein DC power applied when forming the first upper electrode layer is smaller than DC power applied when forming the second upper electrode layer.

7. The method of claim 6, wherein the DC power applied when forming the first upper electrode layer is smaller than DC power applied when forming the lower electrode layer.

8. The method of claim 6, further comprising:
performing a heat treatment process after the forming of the first upper electrode layer.

9. The method of claim 1, wherein the forming of the upper electrode layer includes:
forming a first upper electrode layer; and
forming a second upper electrode layer over the first upper electrode layer,
wherein a nitrogen content of the first upper electrode layer is smaller than a nitrogen content of the second upper electrode layer.

10. The method of claim 9, wherein the first upper electrode layer contains no nitrogen.

11. The method of claim 9, wherein a thickness of the first upper electrode layer is smaller than a thickness of the second upper electrode layer.

12. The method of claim 1, further comprising one or more of:
forming a lower resistance layer positioned below the lower electrode layer before the forming of the lower electrode layer; and
forming an upper resistance layer positioned over the upper electrode layer after the forming of the upper electrode layer.

13. A method for fabricating a semiconductor device, the method comprising:
forming a lower electrode layer;
forming a memory layer over the lower electrode layer;
forming a first upper electrode layer containing carbon over the memory layer; and
forming a second upper electrode layer containing carbon over the first upper electrode layer,
wherein DC power applied when forming the first upper electrode layer is smaller than DC power applied when forming the second upper electrode layer.

14. The method of claim 13, wherein the DC power applied when forming the first upper electrode layer is smaller than DC power applied when forming the lower electrode layer.

15. The method of claim 13, further comprising:
performing a heat treatment process after the forming of the first upper electrode layer.

16. The method of claim 13, wherein a nitrogen content of the first upper electrode layer is smaller than a nitrogen content of the second upper electrode layer.

17. The method of claim 16, wherein the first upper electrode layer contains no nitrogen.

18. The method of claim 16, wherein a thickness of the first upper electrode layer is smaller than a thickness of the second upper electrode layer.

19. The method of claim 13, further comprising one or more of:
forming a lower resistance layer positioned below the lower electrode layer before the forming of the lower electrode layer; and
forming an upper resistance layer positioned over the second upper electrode layer after the forming of the second upper electrode layer.

20. A semiconductor device, comprising:
a lower electrode containing carbon;
a memory pattern positioned over the lower electrode; and
an upper electrode including a first upper electrode and a second upper electrode, the first upper electrode positioned over the memory pattern and containing carbon, the second upper electrode positioned over the first upper electrode and containing carbon,
wherein a density of the first upper electrode is greater than a density of the second upper electrode.

21. The semiconductor device of claim 20, wherein a density of the lower electrode is greater than the density of the second upper electrode.

22. The semiconductor device of claim 20, wherein a surface roughness of the second upper electrode is greater than a surface roughness of the first upper electrode.

23. The semiconductor device of claim 20, wherein a surface roughness of the second upper electrode is greater than a surface roughness of the lower electrode.

24. The semiconductor device of claim 20, wherein a nitrogen content of the first upper electrode is smaller than a nitrogen content of the second upper electrode.

25. The semiconductor device of claim 20, wherein a thickness of the first upper electrode is smaller than a thickness of the second upper electrode.

26. The semiconductor device of claim 20, wherein the lower electrode includes a first lower electrode and a second lower electrode positioned over the first lower electrode.

27. The semiconductor device of claim 26, wherein a nitrogen content of the first lower electrode is greater than a nitrogen content of the second lower electrode.

28. The semiconductor device of claim 26, wherein a thickness of the first lower electrode is greater than a thickness of the second lower electrode.
